(19) United States
(12) Patent Application Publication
(10) Pub. No.: US 2006/0092050 A1
(43) Pub. Date: May 4, 2006

(54) Trellis constellation shaping

(76) Inventors: Igor S. Djokovic, Costa Mesa, CA (US); Richard D. Wesel, Manhattan Beach, CA (US)

Correspondence Address: WEIDE & MILLER, LTD., 7251 W. LAKE MEAD BLVD., SUITE 530, LAS VEGAS, NV, 89128, US

(21) Appl. No.: 11/244,488

(22) Filed: Oct. 5, 2005

Related U.S. Application Data
(60) Provisional application No. 60/616,046, filed on Oct. 5, 2004.
(60) Provisional application No. 60/616,045, filed on Oct. 5, 2004.

(51) Int. Cl. H03M 7/00

(52) U.S. Cl. 341/50

(57) ABSTRACT

A method for trellis constellation shaping is disclosed. In one embodiment, this method comprises receiving two or more input bits and filtering at least one of the two or more input bits to create two or more filtered output bits. The step of filtering at least one input bit introduces at least one extra bit. The method then encodes the input bits which are not filtered to create encoded bits and stores the encoded bits and the filtered bits in a buffer. A processing element may be configured to perform Viterbi type processing on the filtered bits to create processed bits. The method combines at least one of the processed bits with at least one of the buffered bits to create a combined bit set from the buffered bits and then performs mapping on the combined bet set to thereby map the combined bit set into a constellation.

### 1. PRIORITY CLAIM

This patent application claims priority to U.S. Provisional Patent Application Ser. No. 60/616,046 entitled Method and Apparatus for Signal Coding, filed Oct. 5, 2004, and U.S. Provisional Patent Application Ser. No. 60/616,045 entitled Trellis Constellation Shaping, filed Oct. 5, 2004.

### 2. FIELD OF THE INVENTION

The invention relates to a communication system and, in particular, to a method and apparatus for communication system coding and constellation shaping.

### 3. RELATED ART

Modern communication systems exchange data between remote locations using complex coding schemes to minimize the bit error rate and maximize the signal to noise ratio. As a result, the data throughput may be maximized. As one coding approach to increase the effective data rate, trellis coded modulation may be adopted.

The basic principles of trellis coded modulation (TCM) are generally understood and, as such, an exhaustive discussion of TCM is not provided beyond the following discussion. TCM is a way of achieving a lower bit error rate (BER) for a given SNR at the expense of increased constellation size. Shaping of the constellation may also occur to improve the transmit rate, reduce code complexity. Prior art constellation shaping does not solve the problems in the art and as a result, an improved method and apparatus for constellation shaping is needed.

### SUMMARY

To overcome the drawbacks of the prior art, a method for trellis constellation shaping is disclosed. In one embodiment, this method comprises receiving two or more input bits and filtering at least one of the two or more input bits to create two or more filtered output bits. The step of filtering at least one input bit introduces at least one extra bit and the output of the filter may be defined as filtered bits. The method then encodes the input bits which are not filtered to create encoded bits and stores the encoded bits and the filtered bits in a buffer to create buffered bits. A processing element may be configured to perform Viterbi type processing on the filtered bits to create processed bits. The method combines at least one of the processed bits with at least one of the buffered bits to create a combined bit set from the buffered bits and then performs mapping on the combined bet set to thereby map the combined bit set into a constellation.

Also disclosed is a system for reducing the average power of a constellation through reshaping. In one embodiment the system comprises an input configured to receive two or more inputs bits and a filter configured to accept and process at least one of the two or more input bits to create two or more filtered bits. In this embodiment the filter introduces at least one extra bit. Also part of this embodiment is an encoder and a bugger. The encoder is configured to received and perform encoder processing on non-filtered input bits to create encoded bits. The buffer is configured to receive the filtered bits and the encoded bits to create buffered bits. Aa decoder is configured to receive and processes the filtered bits to create one or more decoded bits. Processing by the decoder reduces average energy. In addition, one or more summing junctions are provided and configured to combine and output the decoded bits with the at least one of the buffered bits. In turn, a mapper is provided and configured to map the buffer output and the summing junctions outputs to a constellation point.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### DESCRIPTION OF THE FIGURES

FIG. 1 illustrates 16-QAM constellation partitioned into 4 cosets.

FIG. 2 illustrates a block diagram of an example embodiment of a shaper as configured in a transmitter.

FIG. 3 illustrates a block diagram of a receiver decoder.

FIG. 4 illustrates a plot of shaping gain as a function of the data rate.

FIG. 5 illustrates a plot of the probability of the shaping bit error.

FIG. 6 illustrates BER curves for an information rate of b=2, 3, . . . 16 bits per bin.

FIG. 7 illustrates signal to noise ratio gain for various bits per bin.

FIG. 8 illustrates a plot of average coding gains for TCM coding alone.

FIG. 9 illustrates a plot of signal to noise ratio gain as a function of the rate at certain bit error rates.

FIG. 10 illustrates a block diagram of a delay for use in a shaper.

FIG. 11 illustrates an example trellis for shaper.

FIG. 12 illustrates a block diagram of an example receiver circuitry

FIG. 13 illustrates a plot of BER and SER curves for a Reed-Solomon code.

FIG. 14 illustrates a plot of Input-output BER curves for different number of check bytes.

FIG. 15 illustrates a plot of interleaving depths of 2, 4, . . . 16 for Reed-Solomon codewords.

FIG. 16 shows the plots of FIG. 15 but for Reed-Solomon codes with 8 check bytes.

### DETAILED DESCRIPTION

Trellis shaping is a technique for reducing average transmit power. Information theory shows that a transmit signal may be required to have Gaussian-like distribution in order to maximize mutual information, a necessary step in approaching Shannon's limit. Maximum shaping gain is 1.53 dB and it can be achieved only asymptotically. With modest complexity, only about 0.6-0.8 dB can be achieved. Disclosed herein are descriptions of simulation results of one such technique as well as implementation details. Theory is described in Forney. G. D. Jr. “Trellis Shaping”, IEEE Trans on Information Theory, March 1992, which is incorporated by reference herein.

Shaping Background

It can be shown that out of all possible probability distributions for a given variance, Gaussian distribution achieves maximum entropy, i.e. is the richest in information content. It is also a necessary step to approach Shannon's bound. In digital communications, distributions are usually uniform, namely, all the constellation points are equally probable. This may be true if 2ⁿ constellation points are used to transmit n random bits. This probably may be changed using an idea that is similar to that of trellis coding, by increasing the constellation size (typically two times) but making points with smaller energy (closer to the coordinate origin) more probable than the outer points. There are several ways of accomplishing this. Described next is one exemplary technique.

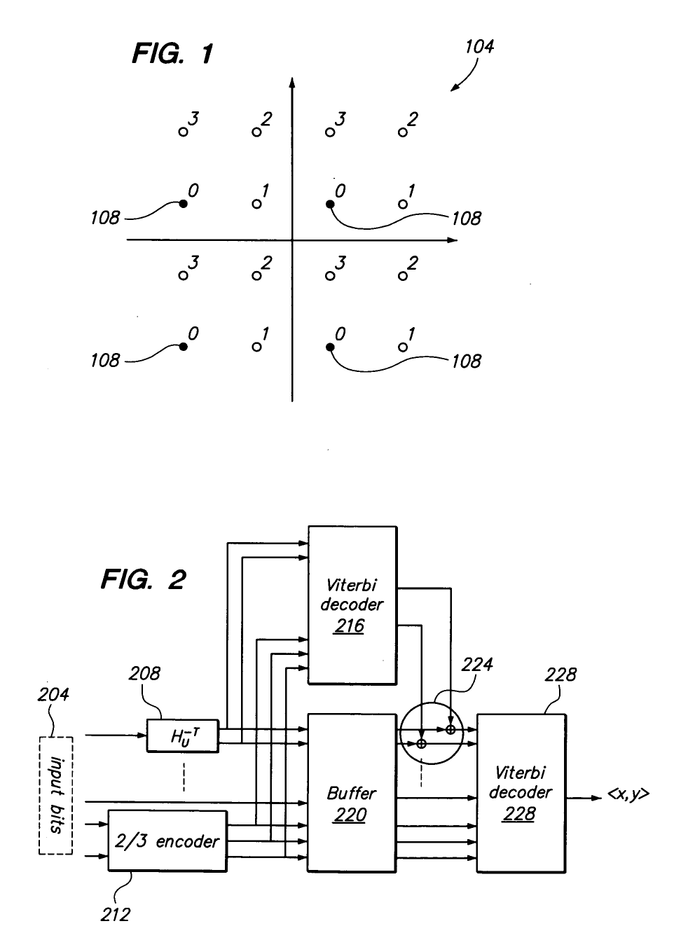

FIG. 1 shows a 16-QAM constellation 104 partitioned into 4 cosets 108 according to the sign bit of its x and y components. Coset ‘0’ is highlighted. Coordinates of these four points are (1,1), (−3,1), (1,−3) and (−3,−3), because in binary representation 1 and 3 differ only by the sign bit (assuming there is one integer bit). This can be similarly extended to higher density constellations. The main idea is to consider these 4 points equivalent in a certain sense and transmit the one with lowest energy (closest to the origin). Theoretically, the gain achieved through shaping is independent of any other gain achieved through coding. In reality, there is already some shaping due to use of cross constellations (its shape is closer to a circle than that of a square). Simulation results show that 0.6-0.9 of shaping gain can be achieved depending on size and shape of constellations. When combined with TCM as described in co-pending provisional application entitled Method and Apparatus for Signal Coding, filed provisionally on Oct. 5, 2004, it is possible to achieve 3-4 dB of gain at BER of 10⁻³ to 10⁴. This is a little short of the straightforward sum of the coding and shaping gains, probably due to implicit shaping of cross constellations.

Simulation

A discussion of the steps to perform shaping is now provided. FIG. 2 shows what additional elements may be provided at the transmitter to implement one example embodiment of a shaper. In FIG. 2 input buts 204 are provided to a filter 208 and an encoder 212. The output of the encoder feeds into a buffer 20 and viterbi decoder 216. The output of the filter 208 feeds into the buffer 220 and the decoder 216. The output of the decoder 216 feeds into summing junctions 224 to be combined with the output of the buffer 220. The output of the buffer 220 and the junctions 224 are provided to a mapper 228.

First, in order to double the size of the constellation, it is possible to introduce one extra bit (MSB) through the feedforward “fiter” 208 H^{-T}_{U}. Entries of this filter 208 depend on the underlying code for which Viterbi decoder 216 operates. It is possible to view the Viterbi decoder 216 and the underlying code as a way of generating a sequence of signs (for x and y components) such that the average energy is minimized. The combined effects of H^{-T}_{U} filter 208 and Viterbi decoder 216 can be undone at the receiver through a simple feedforward “filter” H^{T}_{U}.

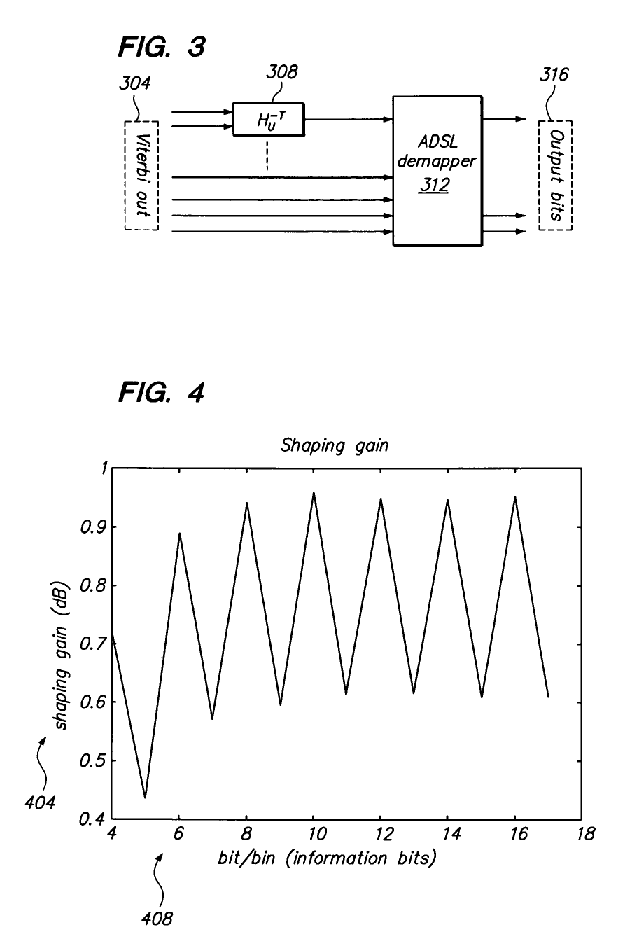

FIG. 3 illustrates a receiver processor. The output of the Viterbie 304 is presented to a filter 308 and a demapper 312 to create output bits 316. Even though it appears that the complexity is increased quite a bit by addition of the Viterbi decoder, it should be noticed that a very simple 4 state code can achieve the above-mentioned shaping gains. Matrices H^{T}_{U} and H^{-T}_{U} are understood by one of ordinary skill in the art. For example, they are [D, 1+D] and [1+D+D², 1+D²].

Simulation Results

The focus is now on the shaping gains that can be expected in a DMT system. In order to make a fair comparison, it is preferred to keep the rate the same and compare the energies of corresponding constellations.

FIG. 4 shows shaping gain as a function of the rate. The vertical axis 404 represents shaping gain in dB while the horizontal axis 408 represents bits per bin. It can be seen that this gain varies quite a bit depending on whether comparing is of square to a cross or the other way around. Since cross already has about 0.15 dB of shaping gain compared to a square, it is responsible for about 0.3 dB of variation peak to peak in this plot. This plot is obtained without the presence of TCM, channel or any other impairment. It is only verified that bits can be recovered without an error at the receiver.

One additional point worth mentioning is the effect of traceback depth on errors. It is clear from the discussions that shaping tries to minimize average energy. In the absence of noise, it should not make any errors. However, at the transmitter, searching for the path having minimum accumulated energy using Viterbi algorithm may be performed. In order to reduce or guarantee no error introduction, it is important that the Viterbi algorithm is implemented without any limitation (e.g., insufficient traceback depth) that would result in an output sequence that does not correspond to a valid state transition sequence. If the traceback depth were as long as one DMT symbol, then this would not be an issue because it would be possible to find a unique optimal path after the entire symbol is processed. On the other end of the extreme is a traceback depth of 1, which will simply pick the lowest energy constellation for each bin, regardless of any disallowed state transitions. A discussion of how the probability of error depends on the traceback depth is now provided.

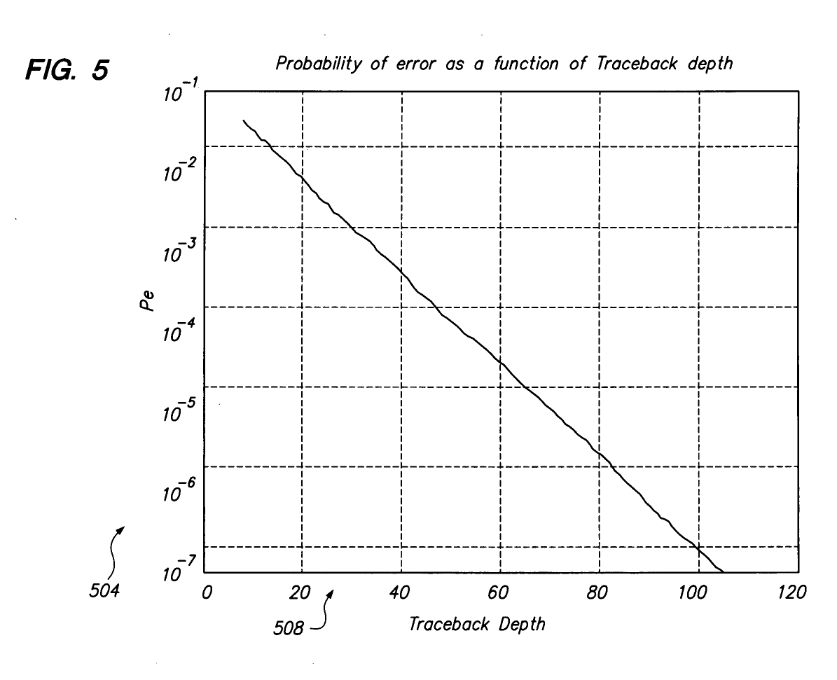

Probability of the shaping bit being in error (in a 5 bit constellation) is shown in FIG. 5. In FIG. 5, the vertical axis 504 represents error probability while the horizontal axis 508 represents traceback depth.

Several conclusions may be reached by looking at FIG. 5. Firstly, for the rather short traceback depths, probability of error is unacceptably high. These are the errors at the output of the demapper and they will be there no matter how high the SNR is (i.e. even in the absence of noise). Therefore, it may be desirable to make sure that the traceback is long enough to make probability of error acceptable. Probability of error decreases one order of magnitude for each increase in traceback depth by approximately 17. If this trend continues, the traceback depth of about 200 (assuming that the system has 6 dB of margin on the top of the operating point corresponding to BER of 10⁻⁷) may be utilized.

As an alternative approach, if a traceback depth less than the DMT symbol length must be used, the shaper can still guarantee no decoding errors at a minimal reduction in shaping gain. This is achieved as follows: when the Viterbi Decoder traceback operation finds that the traced back paths have not merged to a single candidate by the end of the trace back buffer, the decoder is forced to flush out the entire trace back buffer and decide the optimal path all the way to the present time. Then the system is reinitialized by making all other states of the present time improbable and starting all future paths as a continuation of the presently decoded path.

BER Curves and Coding Gain

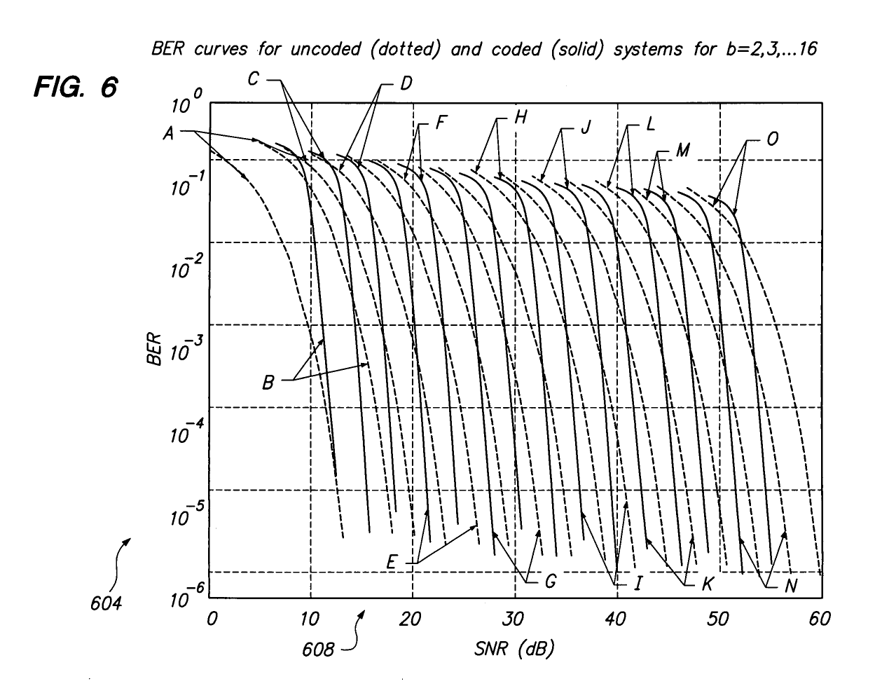

Ultimately, what may be desired is BER as a function of SNR with TCM and shaping. FIG. 6 shows exactly this (64 state code). In FIG. 6, the vertical axis 604 bit error rate while the horizontal axis 608 represents signal to noise ratio on dB. For plots b=2, 3, 4, . . . 16, the plots are labeled A, B, C, . . . O respectively. It is rather hard to see how the combination of shaping and coding gain depends on SNR or BER. To get a better insight, a discussion of the SNR gain (difference between SNR of coded, shaped and uncoded systems with the same information rate) at different BERs is now provided.

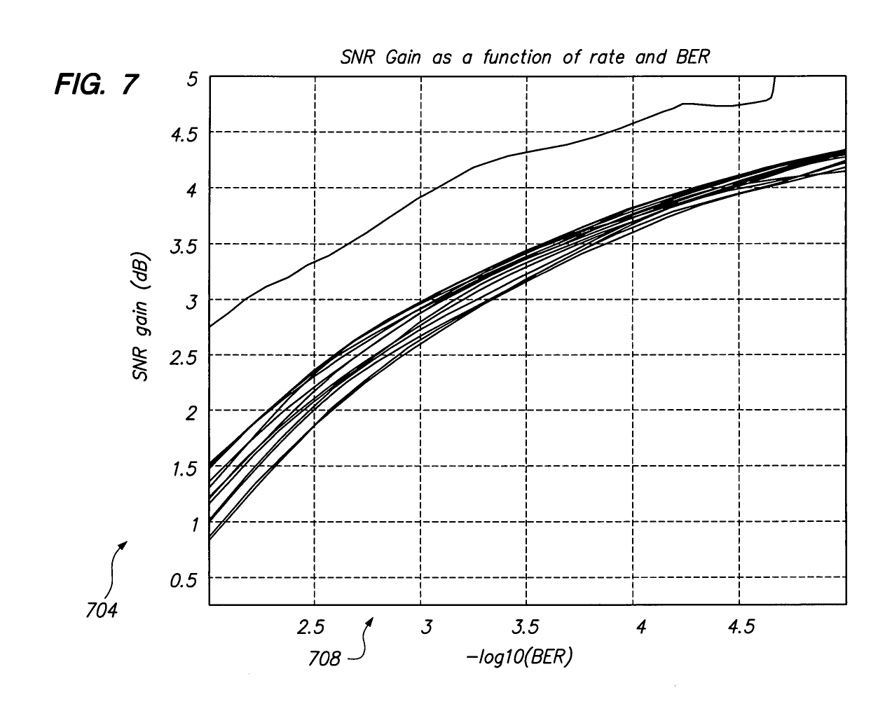

FIG. 7 illustrates SNR gain for various bits per bin. In FIG. 7, the vertical axis 704 represents signal to noise ratio while the horizontal axis 708 is a logarithmic scale representation of bit error rate. From this plot, it is much easier to see how SNR gain depends on the output BER. Only a range of 10⁻² to 10⁻⁵ is shown because RS will clean up most of the errors and the final BER will be well below 10⁻⁷. It can be shown that the asymptotic gain is bigger. This means that with relatively simple RS code, it is possible to achieve very low bit error rates.

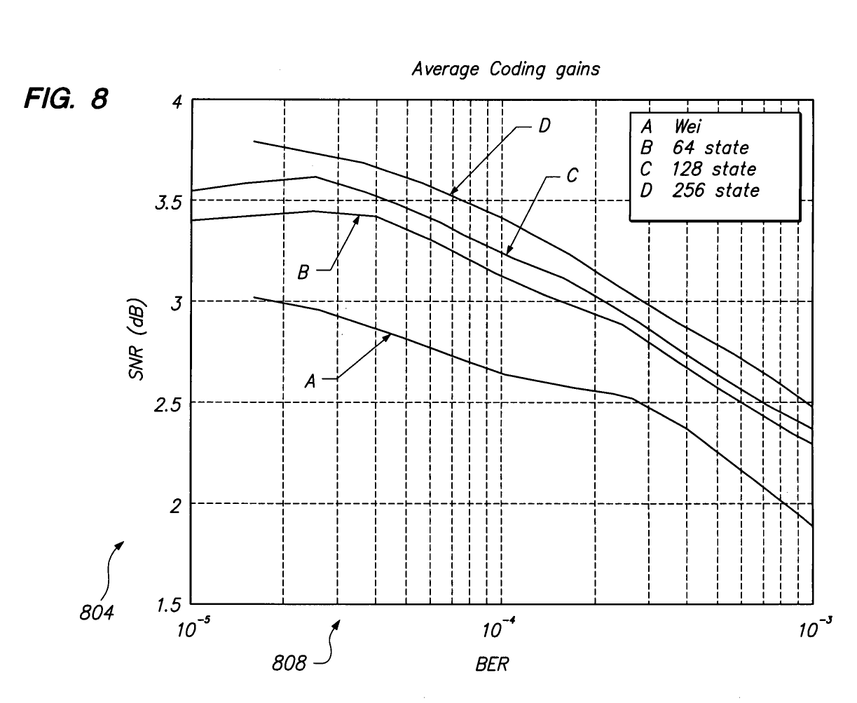

A comparison of curves with the coding gain from TCM alone is now provided. For convenience, corresponding curves for TCM are shown in FIG. 8. In particular, FIG. 8 illustrates average coding gains for TCM alone. In FIG. 8, the vertical axis 804 represents signal to noise ratio, in dB, while the horizontal axis 808 represents bit error rate.

Although the, horizontal axis runs the other way and it is not logarithmic, it is still fairly easy to compare gains at different BERs. It can be shown that at 10⁻⁵ there is about 0.7 dB (4.3-3.6) of extra SNR gain due to shaping. Similar results can be obtained at 10⁻⁴ and 10⁻³. It appears possible to get almost all of the promised shaping gain (or its average) in FIG. 4.

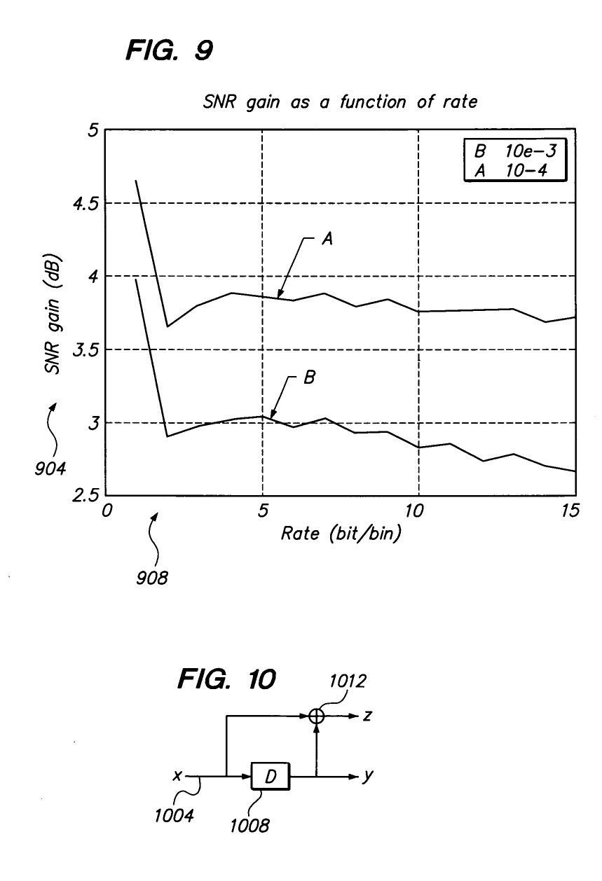

Finally, yet another way of visualizing performance of this system is to plot SNR gain as a function of the rate at certain BER. This is shown in FIG. 9, which illustrates a plot of SNR gain, on the vertical axis 904 as a function of rate, shown on the horizontal axis 908. The curve corresponding to b=3 bits per bin (information bits) stands out because it the SNR gain between b=5 coded and b=3 uncoded. This embodiment compares the best and the worst constellation from the energy compaction point of view, so this case does not have much effect on the overall system performance. It is expected that most of the bins will be loaded with b>5, so the final performance will be some average of the rest of the curves.

Shaper Structure

In this section, details of implementation of the shaper will be described. As shown in FIG. 2, starting with matrix H^{-T}_{U}=[D, 1+D]. This can be implemented with only one delay element as shown in FIG. 10, shown as an input 1004 connected to a delay 1008 and a summing junction 1012. The output of the delay 1008 also feeds into the summing junction 1012. The y output is the output of the delay 1008 while the z output is the output of the summing junction 1012.

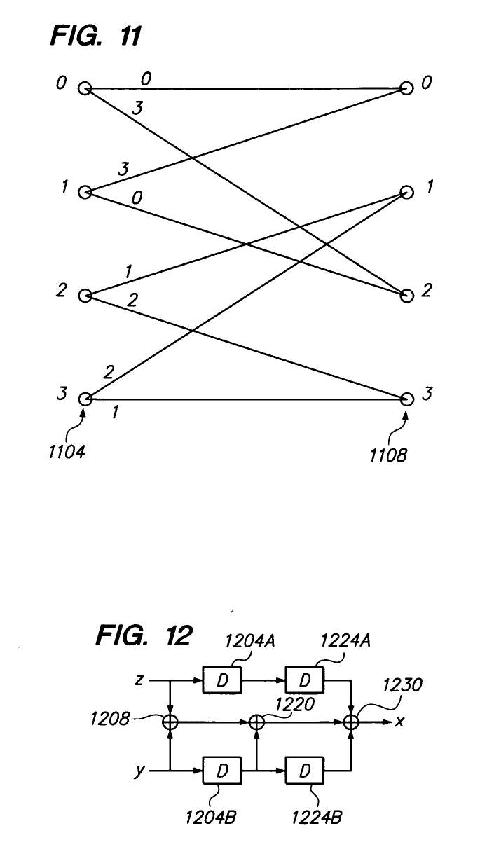

The main purpose of this block is to convert the information MSB into two bits that will be sign bits for x and y coordinates. These two bits may be required to be modified to get all possible combinations (0,0), (0,1), (1,0) and (1,1). These four combinations of sign bits will be mapped into four points (in a fashion similar to that shown in FIG. 1). Computations may occur to find the squared distance from each of the four point to the origin (energy of the point) and pass those four squared distances to the Viterbi decoder. Since the Viterbi decoder has inherent delay, there may be a buffer in the lower part as shown in FIG. 2. The buffer depth has to be the same as the traceback depth of the Viterbi decoder. This traceback depth may be relatively big (64 in simulations) to insure that the process does not switch paths to avoid creating errors. But as it was mentioned earlier, for the underlying code defined by [1+D², 1+D+D²], there are only 4 states and only 2 branches going into each of the states. The corresponding trellis is shown in FIG. 11 having a starting point 1104 and ending point 1108. Branches are labeled with numbers 0-3, which are the two MSBs (or binary representation of the four combinations of different points at the input to the Viterbi decoder). Even though labeling of branches is not relevant, it is important to be consistent, namely, y and z in FIG. 10 correspond to MSB and next to MSB, respectively. Also, the Viterbi decoder will output a branch index (after delay equal to traceback depth) and this number (or these two bits) will be “XOR-ed” with corresponding two MSBs (y and z in FIG. 10). Finally, bits modified in this way will be passed to the mapper.

There is no issue of trellis termination. Consequently, any trellis state may be the ending state, but it may be desirable that the chosen (minimum energy) path is a valid one. So, when the Viterbi decoder reaches the last bin, it will just dump all the states corresponding to the path with minimum accumulated energy. This is in contrast to the Viterbi decoder for TCM, which outputs states corresponding to the path leading to the “zero” state. At the beginning of every DMT symbol, start occurs from a “zero” state, so the delay elements in H^{T}_{U} and H^{-T}_{U} may be required to be initialized to zeros. Again, this process does not care what state they end up in.

The situation is less complex at the receiver. There is only one “filter” as shown in FIG. 12, but it may be desirable to be consistent, y and z correspond to the MSB and next to the MSB bits, respectively. In FIG. 12, inputs y and z connect to delays 1204A, 1204B and summing junction 1208 as shown. The outputs of the delays 1204 connect to a summing junction 1220 and delays 1224A, 1224B as shown. The output of delays 1224 and summing junction 1220 are provided to junction 1230 to create an output x. It should be noted, that in the absence of Viterbi, and modification of the two MSBs with Viterbi's output, H^{T}_{U} at the receiver effectively inverts H^{-T}_{U} operations performed at the transmitter. Any sequence produced by the Viterbi output after going through H^{T}_{U} at the receiver, produces a “zero” sequence. This is an important concept behind trellis shaping and is achieved by choosing Trellis code polynomials for the shaper that lie in the syndrome space of receiver filter H^{T}_{U}. One embodiment utilizes a Viterbi decoder to find a sequence that minimizes average energy, but which is transparent to the receiver.

Bit Wordlengths and Scaling

Squared energies of 4 different points will be fed into the Viterbi decoder. Assuming that the constellations are bounded by 1 (i.e. |x|<1 and |y|<1), and taking into account that the data is unsigned (magnitude squared), it is possible to represent the energy of each point in 1.f format, where f will be no less than 10 bits. Inside the Viterbi decoder, it may be desirable to keep track of the accumulated energy for each path, since in this embodiment, the maximum path length is 32 and the accumulator may be in 6.f format.

Energy of four candidate points at the input to the Viterbi decoder may be required to be scaled according to the bit loading for that bin. This may be necessary since different constellations have slightly different unshaped powers that may be equalized. Otherwise, the shaper will favor certain bins over others.

Concatenation with RS code

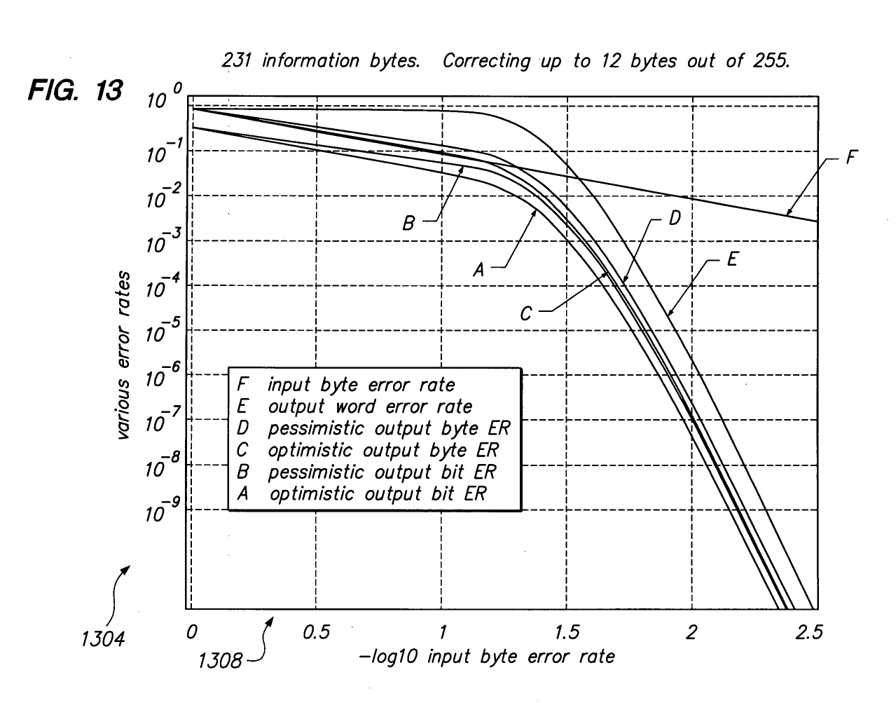

Reed-Solomon may be used as an outer code. In one embodiment, the BER of interest is at or after the RS decoder. Assuming that the interleaver distributes bursty errors at the Viterbi output to make them more independent, the BER or SER (symbol means byte here) may be determined at the RS decoder input to achieve desired output BER. For this, it is possible to use input-output BER curves for RS codes. One set of such curves is shown in FIG. 13 wherein the vertical axis 1304 represents the various error rates, as defined in the Key in FIG. 13, and the horizontal axis 1308 represents the input byte error rate. Since going from BER to SER and back involves making some assumptions on the number of bits in error in any particular byte in error, there are pessimistic and optimistic curves. It can be seen that there is not much difference. These curves are for the RS code that can correct up to 12 errors.

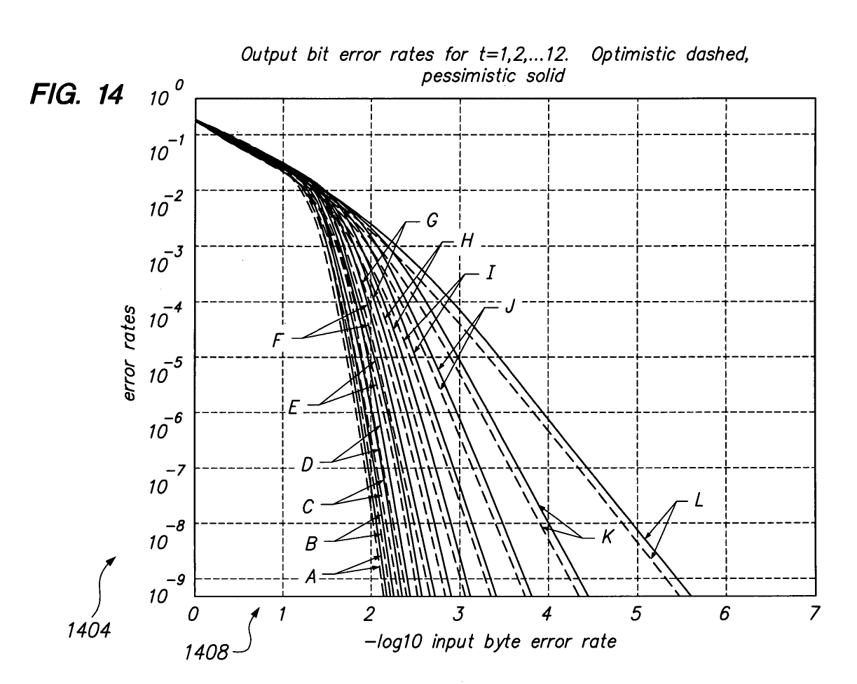

FIG. 14 illustrates how these curves change with the number of correctable errors. In FIG. 14, the vertical axis 1404, represents error rates while the horizontal axis 1408 represents input byte error rate. The plots for t=1, 2, 3, 4, . . . 12 are labeled A, B, C, . . . . L respectively. It shows pessimistic (solid) and optimistic (dashed) input-output curves for RS codes that can correct 1-12 errors. For reference, byte error rate at the Viterbi decoder output is about 3-4 times higher than BER, i.e. on average, there are about two error bits in each error byte.

One can fairly easily read off necessary byte error rate at the input to the RS decoder to achieve the desired output bit error rate. Then from BER plots (like the one in FIG. 6) read off necessary SNR. This simplified analysis does not take into account the bursty nature of errors at the Viterbi output. More importantly, it does not take into account the effect of “error propagation” in MIMO, namely, when a Viterbi makes an incorrect decision, the error used to cancel noise in one or more subsequent lines will be incorrect as well. This effect alone may require Viterbi to operate in a region of much lower BER than needed for RS code to produce output BER of 10⁻⁷ or even 10⁻⁹.

Interleaver

Interleaver may be another essential block of a concatenated TCM-RS coding system. Errors at the output of the Viterbi decoder are bursty in nature. Typically, when Viterbi makes an error due to a particularly bad sequence of noise samples, output will be incorrect until that path merges with the correct one. After that, there will be no errors for a very long time. From the standpoint of the RS decoder, this means that there will be many RS codewords with no errors and every now and then a codeword with quite a few error bytes. It is apparent that the system may not be using proper resources (check bytes) in the best manner. An interleaver is inserted both at the transmitter and receiver between inner (TCM) and outer (RS) codes. Unfortunately, the interleaver introduces extra delay. Depending on the application, this delay may or may not be tolerable. This section discusses the BER curves of concatenated TCM and RS codes for different interleaver depths.

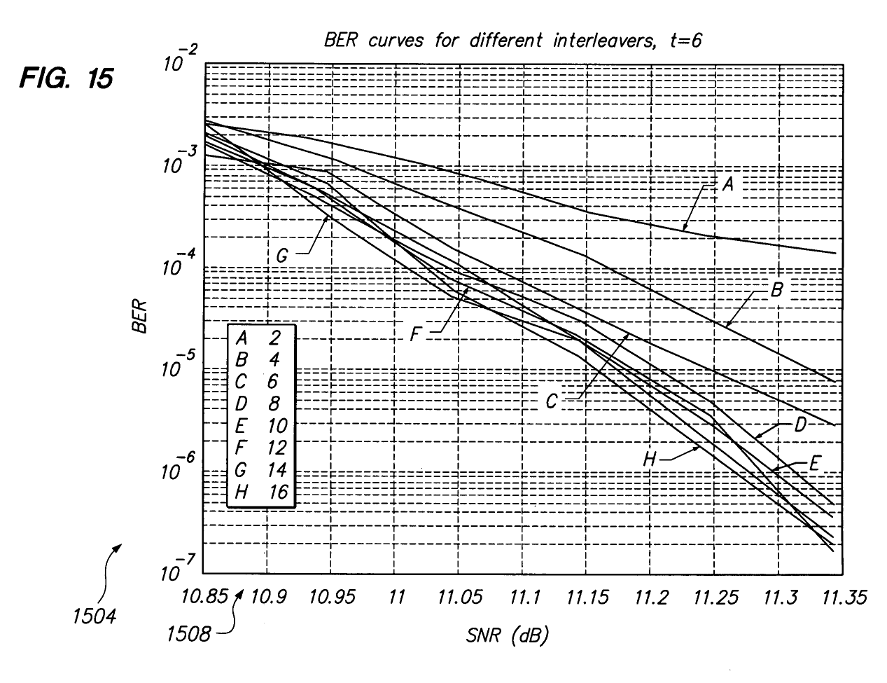

FIG. 15 illustrates a set of BER curves for a t=6 (12 check bytes) RS code. In FIG. 15, the vertical axis 1504 represents the bit error rates while the horizontal axis 1508 represents the signal to noise ratio in dB. The curves are labeled with alpha identifies and the key is provided within FIG. 15. Different curves correspond to different interleaver depths, i.e. how many RS codewords Viterbi errors are distributed. Interleaving may be implemented using a block interleaver.

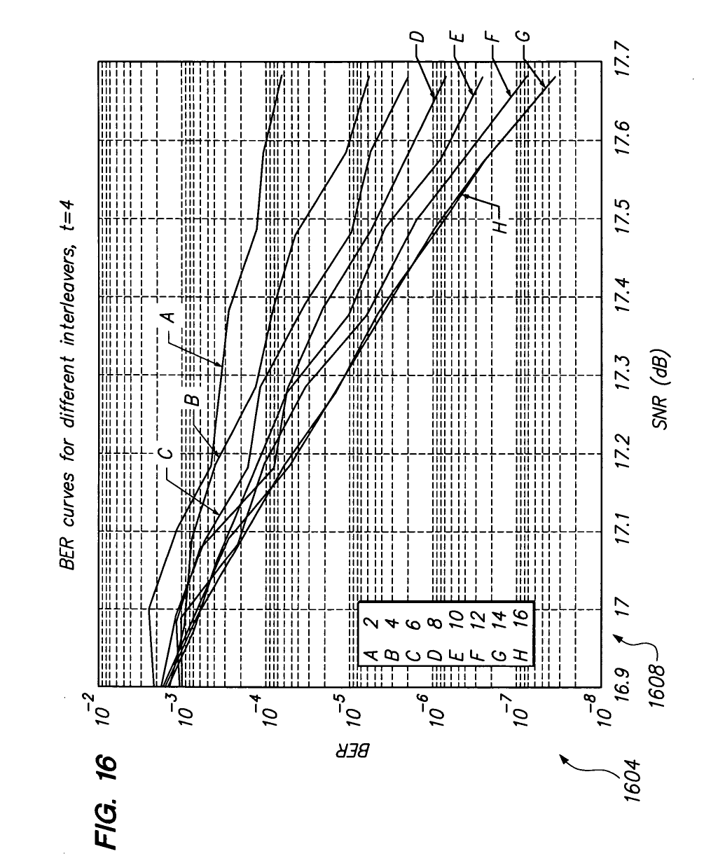

It can be shown that for this code, there is a rather big difference in BER between interleaving 2 and 8 RS codewords (overhead is the same, yet at BER of 10⁻⁴, SNR difference is 0.35 dB). FIG. 16 illustrates the same plots as shown in FIG. 15, but for RS code with 8 check bytes (t=4). In FIG. 16, the vertical axis 1604 represents bit error rate while the horizontal axis 1608 represents signal to noise ratio in dB. The plots are labeled as shown. The main difference is that BER keeps on improving more uniformly as the interleaver depth is increased.

As for the downside for the RS code in terms of check bytes and how they translate into SNR, it depends on the constellation size. RS overhead is a percentage of the total number of bits. For different constellations, this means that the SNR penalty is different. In reality, for a particular SNR profile (i.e. bitload profile), total overhead due to RS check bytes should be added up and divided equally among the bins. It can also be shown that each bit in a constellation accounts for approximately 3 dB. This way the SNR equivalent of the RS overhead may be calculated. However, this will vary among the loops. In general, if for an RS overhead of 2-5%, and 3-4 RS codewords per DMT symbol then the SNR penalty for the overhead bytes will be 2-4 dB.

### CONCLUSION

Discussed herein are the combined effects of coding and shaping. Both techniques aim at reducing the error rate for a given SNR, but the approaches are different. Simulation results confirm that most of the promised gain (about 0.7 dB) can be achieved regardless of the presence of TCM. The following document is incorporated by reference herein, in its entirety. [F1] Forney, G. D. Jr. “Trellis Shaping”, IEEE Trans on Information Theory, March 1992.

Other systems, methods, features and advantages of the invention will be or will become apparent to one with skill in the art upon examination of the figures and detailed description provided herein. It is intended that all such additional systems, methods, features and advantages be included within this description, be within the scope of the invention, and be protected by the accompanying claims.

In addition, the components in the figures are not necessarily to scale, emphasis instead being placed upon illustrating the principles of the invention. In the figures, like reference numerals designate corresponding parts throughout the different views.

While various embodiments of the invention have been described, it will be apparent to those of ordinary skill in the art that many more embodiments and implementations are possible that are within the scope of this invention.

1. A method for trellis constellation shaping comprising:
receiving two or more input bits;
filtering at least one of the two or more input bits to create two or more filtered output bits, wherein filtering the at least one input bit introduces at least one extra bit and the output of the filter comprises filtered bits;
encoding the input bits which are not filtered to create encoded bits;
storing the encoded bits and the filtered bits in a buffer to create buffered bits;
viterbi processing the filtered bits to create processed bits;
combining at least one of the processed bits with at least one of the buffered bits to create a combined bit set from the buffered bits;
performing mapping on the combined bet set to thereby map the combined bit set into a constellation.

2. The method of claim 1, wherein the filtering and viterbi processing reduce the power level of the constellation.

3. The method of claim 1, wherein the filtering comprises feedforward type filtering.

4. The method of claim 1, wherein the viterbi processing generates a sequence of signs for x and y components in the constellation that minimize average energy.

5. The method of claim 1, wherein the viterbi processing comprises use of a 4 state code to achieve shaping gains.

6. The method of claim 1, wherein the method is performed in a multi-channel communication device and wherein constellation size varies across channels.

7. The method of claim 1, wherein storing comprises delaying.

8. A system for reducing the average power of a constellation through reshaping, the system comprising:
an input configured to receive two or more inputs bits;
a filter configured to accept and process at least one of the two or more input bits to create two or more filtered bits, wherein the filter introduces at least one extra bit;
an encoder configured to received and perform encoder processing on non-filtered input bits to create encoded bits;
a buffer configured to receive the filtered bits and the encoded bits to create buffered bits;
a decoder configured to receive and processes the filtered bits to create one or more decoded bits, wherein the processing by the decoder reduces average energy;
one or more summing junctions configured to combine and output the decoded bits with the at least one of the buffered bits;
a mapper configured to map the buffer output and the summing junctions outputs to a constellation point.

9. The system of claim 8, wherein the filter introduces an additional bit thereby doubling the size of the constellation.

10. The system of claim 8, wherein the encoder comprises a 2/3 encoder configured to receive two of the input bits and output three encoded bits.

11. The system of claim 8, wherein the buffer comprises one or more delays.

12. The system of claim 8, wherein the mapper generates an x and y output.

13. The system of claim 8, wherein the decoder utilizes a four state code.
